(19) United States
(12) Patent Application Publication
(10) Pub. No.: US 2023/0352397 A1
(43) Pub. Date: Nov. 2, 2023

(54) SEMICONDUCTOR DEVICE AND METHOD OF MANUFACTURING THE SEMICONDUCTOR DEVICE

(71) Applicant: RENESAS ELECTRONICS CORPORATION, Tokyo (JP)

(72) Inventor: Eiji HIRAIWA, Tokyo (JP)

(21) Appl. No.: 18/176,671

(22) Filed: Mar. 1, 2023

(30) Foreign Application Priority Data
Apr. 28, 2022 (JP) 2022-074506

(51) Int. Cl. H01L 23/522; H01L 21/3213

(52) U.S. Cl. CPC H01L 23/5223; H01L 21/32135

(57) ABSTRACT

A semiconductor device in which a resistance film and a MIM capacitor can be arranged within an interlayer insulating film without increasing the thickness of the interlayer insulating film is provided. The semiconductor device comprises the interlayer insulating film and resistance film, lower electrode and upper electrode membranes disposed within the interlayer insulating film. The interlayer insulating film includes a first layer, a second layer, and a third layer. A resistance film and a lower electrode film are disposed on the first layer. A resistance film and the lower electrode film are made of the same material. An upper electrode film faces the lower electrode film with the second layer interposed therebetween. The third layer cover resistance film, the lower electrode film and the upper electrode film.

### CROSS-REFERENCE TO RELATED APPLICATIONS

The disclosure of Japanese Patent Application No. 2022-074506 filed on Apr. 28, 2022, including the specification, drawings and abstract is incorporated herein by reference in its entirety.

### BACKGROUND

The present disclosure relates to a manufacturing method of a semiconductor device and the semiconductor device.

For example, Japanese Patent Laid-Open No. JP-A-2011-155192 (Patent Document 1) disclose a semiconductor device. The semiconductor device of Patent Document 1 includes wiring layer, an interlayer insulating film, a metal resistance film, and via plugs. The interlayer insulating film has a first layer and a second layer. The first layer covers wiring layer. The metal resistance film is disposed on the first layer. The second layer covers the metal resistance film. The via plugs is electrically connected to the wiring layer by embedded in a via hole formed in the first layer.

### SUMMARY

A MIM (Metal Insulator Metal) capacitor includes a lower electrode film and an upper electrode film facing to the lower electrode film each other. When such the MIM capacitor and the metal resistance film of the semiconductor device described in Patent Document 1 are arranged in one interlayer insulating film, the thickness of the interlayer insulating film is increased. Other objects and novel features will become apparent from the description of this specification and the accompanying drawings.

The semiconductor device includes an interlayer insulating film and a resistance film, a lower electrode film, and an upper electrode film disposed in the interlayer insulating film. The interlayer insulating film includes a first layer, a second layer, and a third layer. The resistance film and the lower electrode film are disposed on the first layer. The resistance film and the lower electrode film are made of the same material. The upper electrode film faces the lower electrode film with the second layer interposed therebetween. The third layer cover the resistance film, the lower electrode film and the upper electrode film.

According to the semiconductor device of the present disclosure, it is possible to arrange the resistance film and the MIM capacitor within the interlayer insulating film without increasing a total thickness of the interlayer insulating film.

### BRIEF DESCRIPTION OF THE DRAWINGS

FIG. 1 is a cross-sectional view of a semiconductor device DEV.

FIG. 2 is a flow chart for manufacturing the semiconductor device DEV.

FIG. 3 is a cross-sectional view for explaining an interlayer insulating film forming step S1.

FIG. 4 is a cross-sectional view for explaining a first wiring layer forming step S2.

FIG. 5 is a cross-sectional view for explaining a first layer forming step S3.

FIG. 6 is a cross-sectional view for explaining a first via plug forming step S4.

FIG. 7 is a cross-sectional view for explaining a first film forming step S5.

FIG. 8 is a cross-sectional view for explaining a second layer forming step S6.

FIG. 9 is a cross-sectional view for explaining a second film forming step S7.

FIG. 10 is a cross-sectional view for explaining a second film patterning step S8.

FIG. 11 is a cross-sectional view for explaining a first film patterning step S9.

FIG. 12 is a cross-sectional view for explaining a third layer forming step S10.

FIG. 13 is a cross-sectional view for explaining a second via plug forming step S11.

FIG. 14 is a cross-sectional view of a semiconductor device DEV1.

FIG. 15 is a flow chart for manufacturing the semiconductor device DEV1.

FIG. 16 is a cross-sectional view for explaining a first wiring layer forming step S13.

FIG. 17 is a cross-sectional view for explaining a second layer forming step S14.

FIG. 18 is a cross-sectional view for explaining a first via plug forming step S15.

FIG. 19 is a cross-sectional view for explaining a resistance film forming step S16.

FIG. 20 is a cross-sectional view for explaining a third layer forming step S17.

FIG. 21 is a cross-sectional view for explaining a second via plug forming step S18.

FIG. 22 is a cross-sectional view of a semiconductor device DEV2.

### DETAILED DESCRIPTION

Details of embodiments of the present disclosure will be described with reference to the drawings. In the following drawings, the same or corresponding parts are denoted by the same reference numerals, and redundant description will not be repeated. Semiconductor device according to the embodiment is a semiconductor device DEV.

(Configuration of the semiconductor device DEV) A configuration of the semiconductor device DEV is described below.

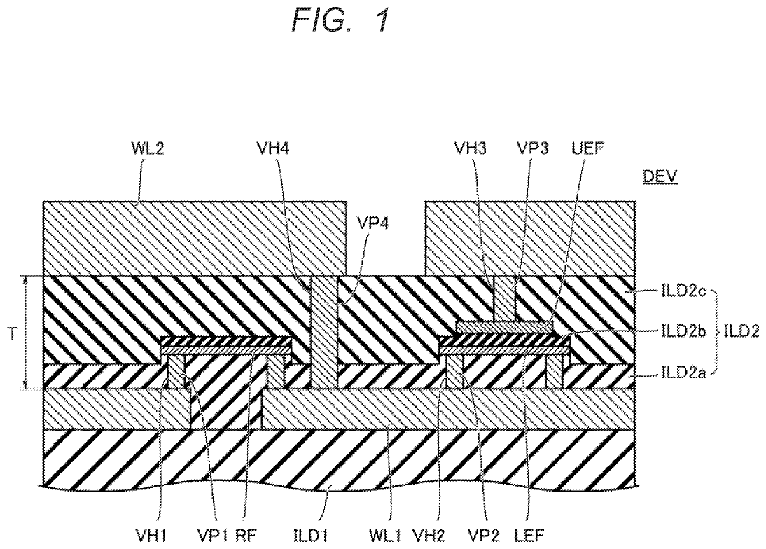

FIG. 1 is a cross-sectional view of the semiconductor device DEV. As shown in FIG. 1, the semiconductor device DEV includes an interlayer insulating film ILD1 and an interlayer insulating film ILD2, a wiring layer WL1 and a wiring layer WL2, a via plug VP1, a via plug VP2, a via plug VP3, and a via plug VP4, a resistance film RF, a lower electrode film LEF, and a upper electrode film UEF.

The interlayer insulating film ILD1 covers wiring layers (not shown). The interlayer insulating film ILD1 is made of, for example, silicon oxide (SiO2). The wiring layer WL1 are arranged on the interlayer insulating film ILD1. The wiring layer WL1 is made of, for example, aluminum (Al) or aluminum alloy. The wiring layer WL1 is, for example, a wiring layer used as a semi-global wiring. That is, the thickness of the wiring layer WL1 is greater than the thickness of the wiring layers below the interlayer insulating film ILD1, and the wiring layer WL1 has a wiring pitch greater than a wiring pitch of the wiring layers below the interlayer insulating film ILD1. The interlayer insulating film ILD2 is made of, for example, silicon oxide. The interlayer insulating film ILD2 includes a first layer ILD2a, a second layer ILD2b, and a third layer ILD2c.

The first layer ILD2a is disposed on the interlayer insulating film ILD1 so as to cover the wiring layer WL1. A via hole VH1 and a via hole VH2 are formed in the first layer ILD2a. The via hole VH1 and the via hole VH2 penetrate the first layer ILD2a along thickness direction. The wiring layer WL1 is exposed from the via holes VH1 and VH2.

The via plug VP1 and the via plug VP2 are embedded in the via hole VH1 and the via hole VH2, respectively. The lower end of the via plug VP1 and the lower end of the via plug VP2 are electrically connected to the wiring layers WL1. The via plug VP1 and the via plug VP2 are made of, for example, tungsten (W).

The resistance film RF and the lower electrode film LEF are disposed on the first layer ILD2a. The resistance film RF is electrically connected to the upper end of the via plug VP1. The lower electrode film LEF is electrically connected to the upper end of the via plug VP2. Thus, the resistance film RF and the lower electrode film LEF are electrically connected to the wiring layers WL1. The resistance film RF and the lower electrode film LEF are made of the same material. The resistance film RF and the lower electrode film LEF are made of, for example, metal material. The metal material includes, for example, at least one selected from the group consisting of silicon chrome (SiCr), carbon (C) introduced silicon chrome (SiCrC), nichrome (NiCr), and tantalum nitride (TaN).

The upper electrode film UEF is arranged on the lower electrode film LEF with the second layer ILD2b interposed therebetween. The lower electrode film LEF is made of, for example, titanium nitride (TiN). The lower electrode film LEF, the upper electrode film UEF, and the second layer ILD2b configure a MIM capacitor. This MIM capacitor is arranged in the interlayer insulating film ILD2. a thickness of the second layer ILD2b is smaller than a thickness of the first layer ILD2a and a thickness of the third layer ILD2c.

The third layer ILD2c covers the resistance film RF, the lower electrode film LEF, and the upper electrode film UEF. The second layer ILD2b is preferably interposed between the resistance film RF and the lower electrode film LEF and the third layer ILD2c. As a result, current leakage between the lower electrode film LEF and the upper electrode film UEF along the interface between the second layer ILD2b and the third layer ILD2c can be suppressed.

A via hole VH3 is formed in the third layer ILD2c. The via hole VH3 penetrates the third layer ILD2c along thickness direction. The upper electrode film UEF is exposed from the via hole VH3. The via plug VP3 is embedded in the via hole VH3. The lower end of the via plug VP3 is electrically connected to the upper electrode film UEF. The via plug VP3 is made of, for example, tungsten.

A via hole VH4 is formed in the interlayer insulating film ILD2 (the first layer ILD2a, the second layer ILD2b, and the third layer ILD2c). The via hole VH4 penetrates the interlayer insulating film ILD2 along thickness direction. The wiring layer WL1 is exposed from the via hole VH4. The via plug VP4 is embedded in the via hole VH4. The lower end of the via plug VP4 is electrically connected to the wiring layer WL1. The via plug VP4 is made of, for example, tungsten.

The wiring layers WL2 is disposed on the interlayer insulating film ILD2 (on the third layer ILD2c). The wiring layer WL2 are made of, for example, aluminum or aluminum alloy. The wiring layer WL2 is, for example, a wiring layer used as a global wiring. That is, the thickness of the wiring layer WL2 is larger than the thickness of the wiring layer WL1, and the wiring layer WL2 has a wiring pitch larger than a wiring pitch of the wiring layer WL1. The wiring layer WL2 is electrically connected to the upper end of the via plug VP3. Thus, the wiring layer WL2 is electrically connected to the upper electrode film UEF. The wiring layer WL2 is connected to the upper end of the via plug VP4. Accordingly, the wiring layer WL2 is electrically connected to the wiring layer WL1.

The thickness of the interlayer insulating film ILD2 is defined as a thickness T. The thickness T is preferably greater than or equal to 650 nm. The thickness T is the thickness of the interlayer insulating film ILD2 between the wiring layer WL1 and the wiring layer WL2. a thickness of the resistance film RF is the same as a thickness of the lower electrode film LEF, and there are about 5 nm. And a thickness of the second layer ILD2b is about 50 nm. A thickness of the upper electrode film UEF is, for example, not less than 50 nm and not more than 80 nm.

(Manufacturing Method of the Semiconductor Device DEV)

Manufacturing method of the semiconductor device DEV is explained below.

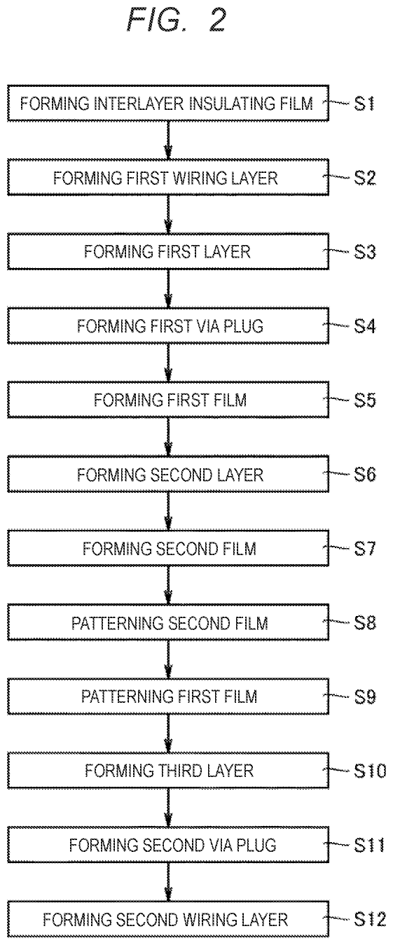

FIG. 2 is a flow chart for manufacturing the semiconductor device DEV. As shown in FIG. 2, the manufacturing method of the semiconductor device DEV includes an interlayer insulating film forming step S1, a first wiring layer forming step S2, a first layer forming step S3, a first via plug forming step S4, a first film forming step S5, a second layer forming step S6, a second film patterning step S8, and a first film patterning step S9. The manufacturing method of the semiconductor device DEV further includes a third layer forming step S10, a second via plug forming step S11, and a second wiring layer forming step S12. Note that structure located below the interlayer insulating film ILD1 may be formed by a conventionally known method, and therefore will not be described here.

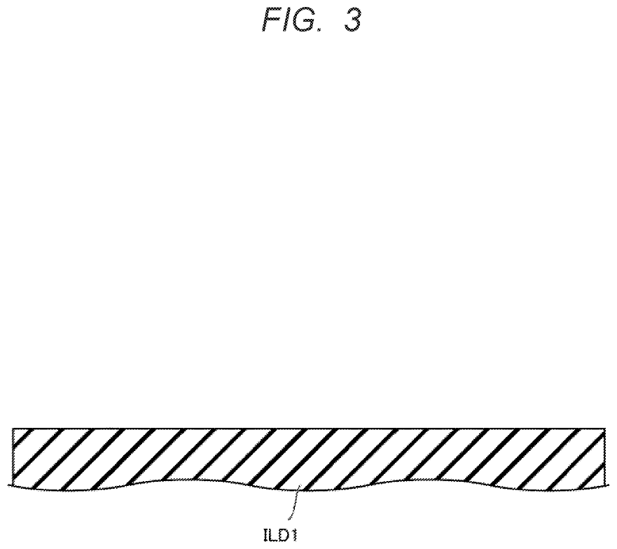

FIG. 3 is a cross-sectional view for explaining the interlayer insulating film forming step S1. In the interlayer insulating film forming step S1, as shown in FIG. 3, the interlayer insulating film ILD1 is formed. In the interlayer insulating film forming step S1, first, a constituent material of the interlayer insulating film ILD1 is deposited by, for example, CVD (Chemical Vapor Deposition). Second, the deposited interlayer insulating film ILD1 is planarized by, for example, CMP (Chemical Vapor Deposition).

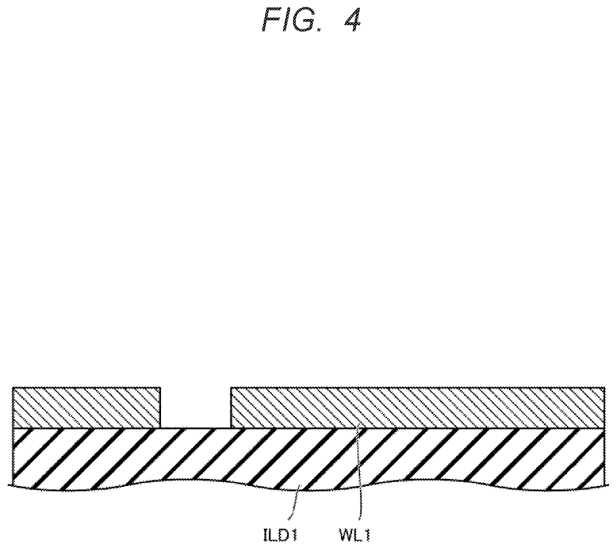

FIG. 4 is a cross-sectional view for explaining the first wiring layer forming step S2. As shown in FIG. 4, in the first wiring layer forming step S2, the wiring layer WL1 is formed. in the first wiring layer forming step S2, first, a constituent material of the wiring layer WL1 is deposited on the interlayer insulating film ILD1 by sputtering, for example. Second, a resist pattern is formed on the constituents of the deposited wiring layers WL1. The resist pattern is formed by exposing and developing the photoresist. Third, dry etching using a resist pattern as a mask is performed to pattern the constituent components of the wiring layer WL1 formed thereon.

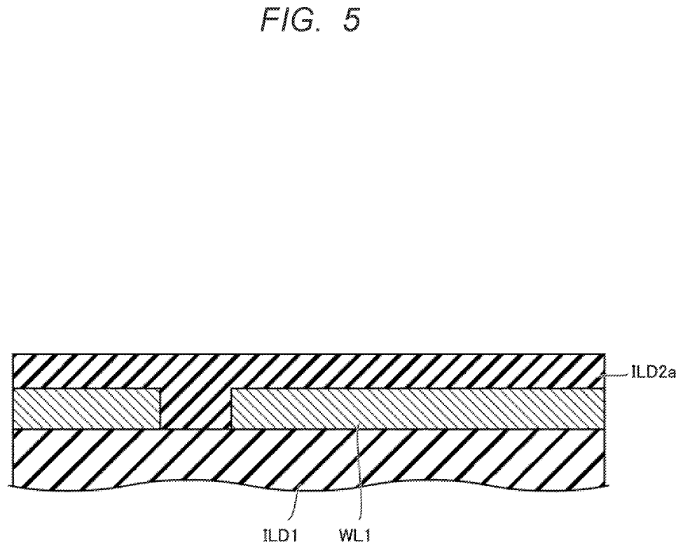

FIG. 5 is a cross-sectional view for explaining the first layer forming step S3. As shown in FIG. 5, in the first layer forming step S3, the first layer ILD2a is formed. In the first layer forming step S3, first, the constituent material of the first layer ILD2a is deposited on the interlayer insulating film ILD1 by CVD, for example. Second, the constituents of the deposited the first layer ILD2a are planarized, for example, by CMP.

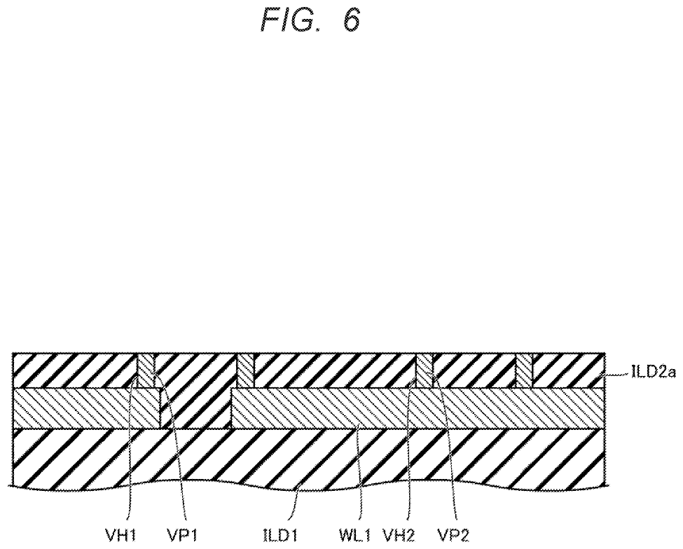

FIG. 6 is a cross-sectional view for explaining a first via plug forming step S4. In the first via plug forming step S4, as shown in FIG. 6, the via plug VP1 and the via plug VP2 are formed. In the first via plug forming step S4, first, a via hole VH1 and a via hole VH2 are formed in the first layer ILD2a. The via hole VH1 and the via hole VH2 are formed by dry etching using a resist pattern formed on the first layer ILD2a as a mask. The resist pattern is formed by exposing and developing the photoresist. Second, for example, by CVD, the constituent material of the via plug VP1 and the constituent material of the via plug VP2 in the via hole VH1 and the via hole VH2 are embedded, respectively. Third, for example, by CMP, the constituent material of the via plug VP1 protruding from the via hole VH1 and the constituent material of the via plug VP2 protruding from the via hole VH2 are removed.

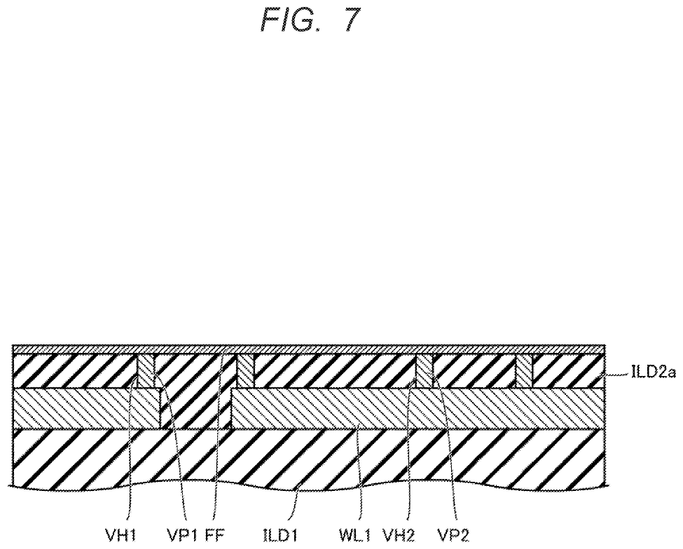

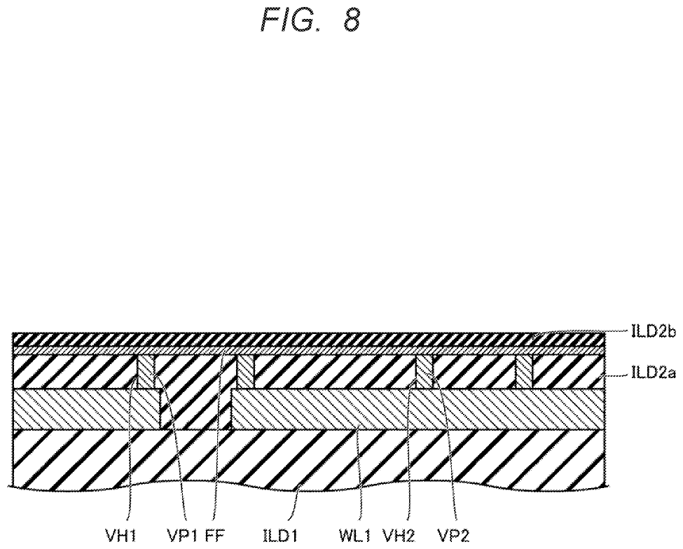

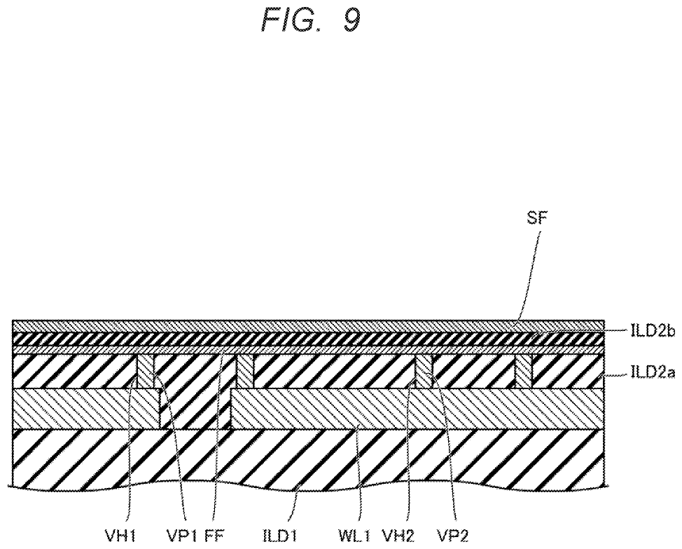

FIG. 7 is a cross-sectional view for explaining the first film forming step S5. As shown in FIG. 7, in the first film forming step S5, a first film FF is formed on the first layer ILD2a. The first film FF is a film made of the resistance film RF. The first film FF is formed by sputtering, for example. FIG. 8 is a cross-sectional view for explaining the second layer forming step S6. As shown in FIG. 8, in the second layer forming step S6, the second layer ILD2b is formed on the first film FF. The second layer ILD2b is formed of, for example, CVD. FIG. 9 is a cross-sectional view for explaining the second film forming step S7. As shown in FIG. 9, in the second film forming step S7, a second film SF is formed. The second film SF is a film formed of a constituent material of the upper electrode film UEF. The second film SF is formed by sputtering, for example.

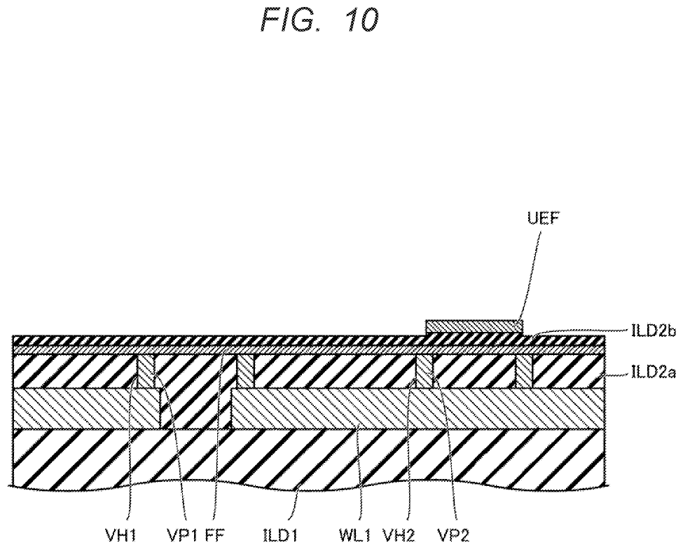

FIG. 10 is a cross-sectional view for explaining a second film patterning step S8. As shown in FIG. 10, in the second film patterning step S8, the second film SF is patterned to form the upper electrode film UEF. First, in the second film patterning step S8, a resist pattern is formed on the second film SF. The resist pattern is formed by exposing and developing the photoresist. Second, the second film SF is patterned by dry etching using the resist pattern as a mask.

At this time, the second layer ILD2b below the second film SF not covered by the resist pattern is also etched, but the second layer ILD2b is preferably not completely removed. That is, it is preferable that the second layer ILD2b covers the first film FF even after the second film patterning step S8 is completed.

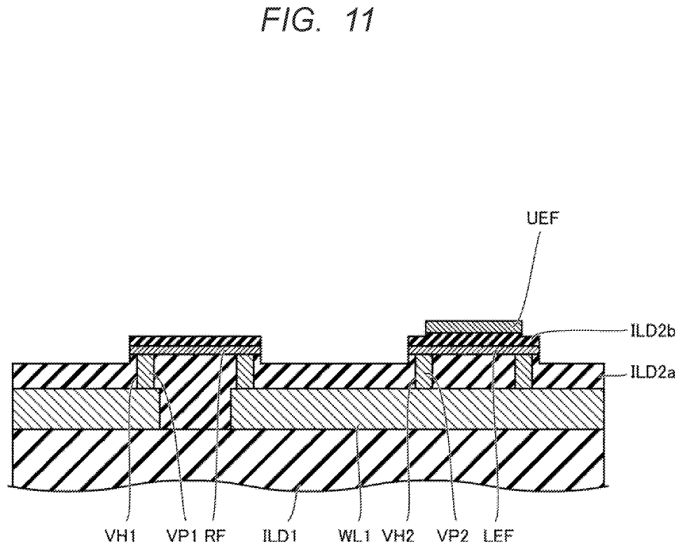

FIG. 11 is a cross-sectional view for explaining a first film patterning step S9. As shown in FIG. 11, in the first film patterning step S9, the first film FF is patterned to form the resistance film RF and the lower electrode film LEF. In the second film patterning step S8, first, a resist pattern is formed on the first film FF (more specifically, on the second layer ILD2b remaining after the etching in the second film patterning step S8). The resist pattern is formed by exposing and developing the photoresist. Second, the first film FF is patterned by dry etching using a resist pattern as a mask.

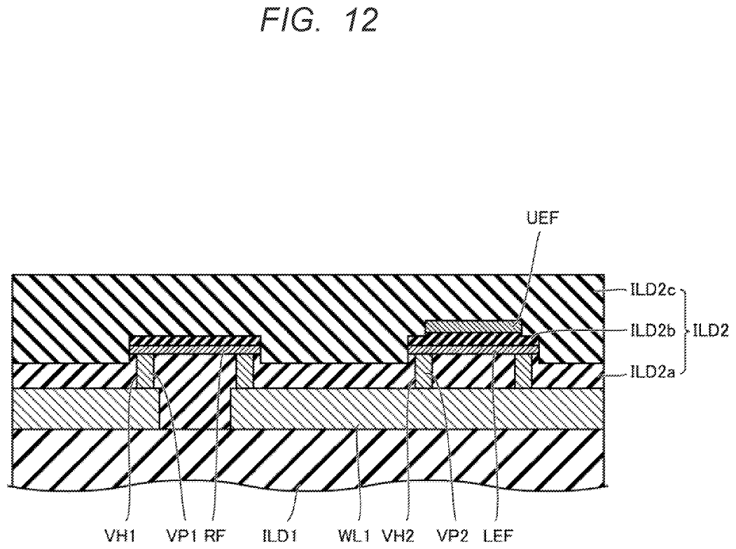

FIG. 12 is a cross-sectional view for explaining the third layer forming step S10. As shown in FIG. 12, in the third layer forming step S10, the third layer ILD2c is formed so as to cover the resistance film RF, the lower electrode film LEF, and the upper electrode film UEF. In the third layer forming step S10, first, the constituent elements of the third layer ILD2c are formed by CVD, for example. Second, the formed third layer ILD2c is planarized by, for example, CMP.

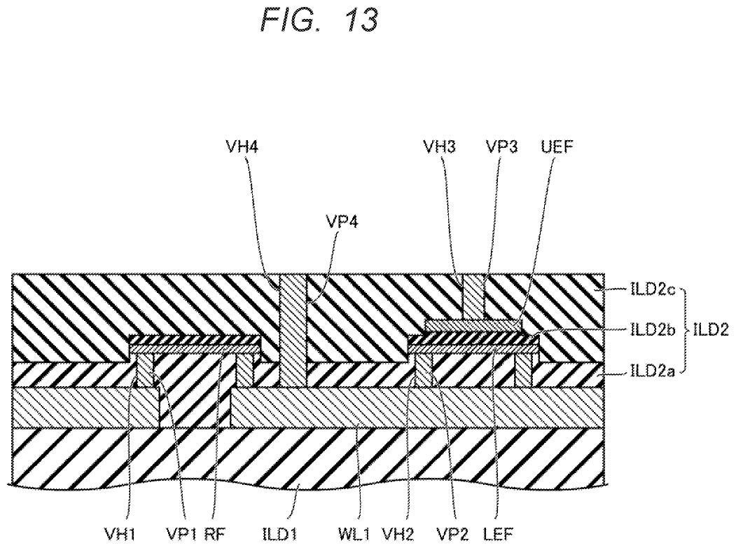

FIG. 13 is a cross-sectional view for explaining the second via plug forming step S11. As shown in FIG. 13, in the second via plug forming step S11, the via plug VP3 and the via plug VP4 are formed. In the second via plug forming step S11, first, the via hole VH3 is formed in the third layer ILD2c, and the via hole VH4 is formed in the interlayer insulating film ILD2. The via hole VH3 and the via hole VH4 are formed by dry etching using a resist pattern formed on the interlayer insulating film ILD2 as a mask. The resist pattern is formed by exposing and developing the photoresist.

Second, for example, by CVD, the constituent material of the via plug VP3 and the constituent material of the via plug VP4 in the via hole VH3 and the via hole VH4 are embedded, respectively. Third, for example, by CMP, the constituent material of the via plug VP3 protruding from the via hole VH3 and the constituent material of the via plug VP4 protruding from the via hole VH4 are removed.

In the second wiring layer forming step S12, the wiring layer WL2 is formed. First, in the second wiring layer forming step S12, a constituent material of the wiring layer WL2 is deposited on the interlayer insulating film ILD2 by sputtering, for example. Second, a resist pattern is formed on the constituents of the deposited the wiring layer WL2. The resist pattern is formed by exposing and developing the photoresist. Third, a dry etching using a resist pattern as a mask is used to pattern the constituent components of the wiring layer WL2 formed thereon. Thus, the semiconductor device DEV of structure shown in FIG. 1 is formed.

(Effect of the Semiconductor Device DEV)

Hereinafter, effects of the semiconductor device DEV will be described in comparison with a semiconductor device according to Comparative Example 1 and a semiconductor device according to Comparative Example 2. The semiconductor device according to Comparative Example 1 is a semiconductor device DEV1, and the semiconductor device according to Comparative Example 2 is a semiconductor device DEV2.

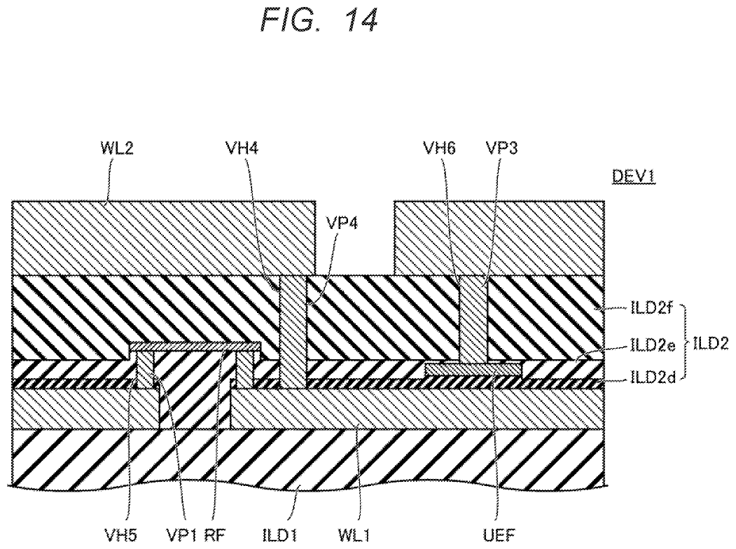

FIG. 14 is a cross-sectional view of the semiconductor device DEV1. As shown in FIG. 14, the semiconductor device DEV1 includes an interlayer insulating film ILD1 and an interlayer insulating film ILD2, a wiring layer WL1 and a wiring layer WL2, a via plug VP1, a via plug VP3, and a via plug VP4, a resistance film RF, and an upper electrode film UEF.

In the semiconductor device DEV1, the interlayer insulating film ILD2 includes a first layer ILD2d, a second layer ILD2e, and a third layer ILD2f. In the semiconductor device DEV1, the upper electrode film UEF is disposed on the wiring layer WL1 with the first layer ILD2d interposed therebetween. That is, in the semiconductor device DEV1, the wiring layer WL1 function as a lower electrode of MIM capacitor. The second layer ILD2e covers the wiring layer WL1 and the upper electrode film UEF. The first layer ILD2d is interposed between the wiring layer WL1 and the second layer ILD2e.

In the semiconductor device DEV1, the resistance film RF is disposed on the second layer ILD2e. A via hole VH5 is formed in the first layer ILD2d and the second layer ILD2e. The via plug VP1 is embedded to the via hole VH5, so that the resistance film RF and the wiring layer WL1 are electrically connected. The third layer ILD2f covers the resistance film RF. A via hole VH6 is formed in the second layer ILD2e and the third layer ILD2f. When the via plug VP3 is embedded to the via hole VH6, the upper electrode film UEF and the wiring layer WL2 are electrically connected to each other.

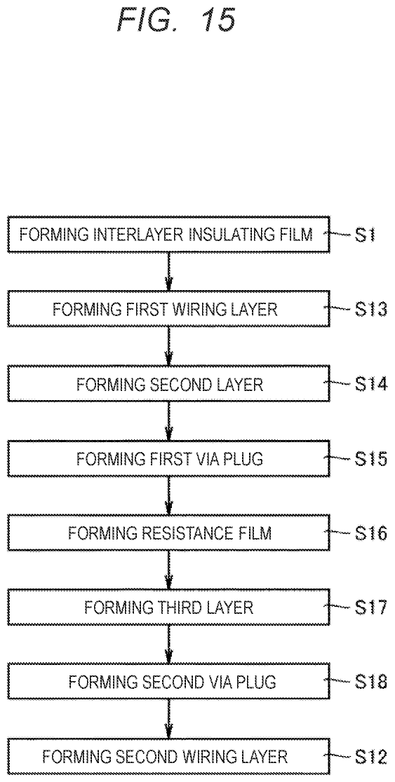

FIG. 15 is a flow chart for manufacturing the semiconductor device DEV1. As shown in FIG. 15, a manufacturing method of the semiconductor device DEV1 includes the interlayer insulating film forming step S1, a first wiring layer forming step S13, a second layer forming step S14, a first via plug forming step S15, a resistance film forming step S16, a third layer forming step S17, a second via plug forming step S18, and the second wiring layer forming step S12.

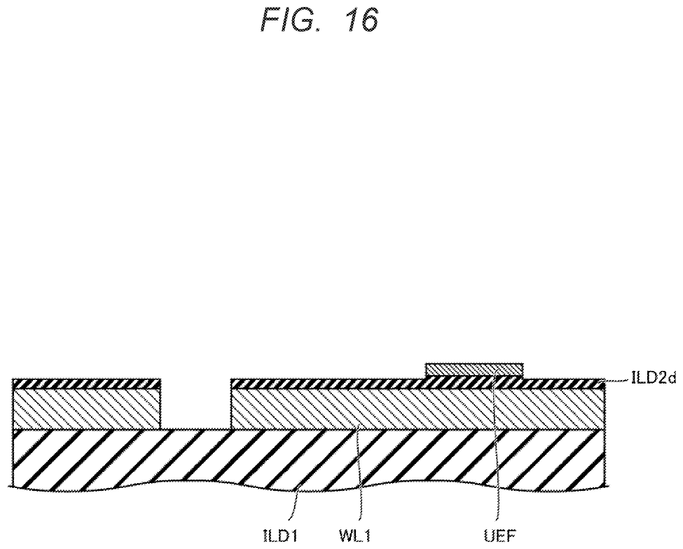

FIG. 16 is a cross-sectional view for explaining the first wiring layer forming step S13. As shown in FIG. 16, in the first wiring layer forming step S13, the wiring layer WL1, the first layer ILD2d, and the upper electrode film UEF are formed. In the first wiring layer forming step S13, first, constituent components of the wiring layer WL1, the first layer ILD2d, and the upper electrode film UEF are sequentially formed. Second, the constituent material of the upper electrode film UEF is patterned by dry etching using the resist pattern formed on the constituent material of the upper electrode film UEF as a mask, and the upper electrode film UEF is formed. After dry etching is performed, the first layer ILD2d remains on the constituent material of the wiring layer WL1. Third, the wiring layer WL1 is patterned by dry etching using the resist pattern formed on the first layer ILD2d as a mask, thereby forming the wiring layer WL1.

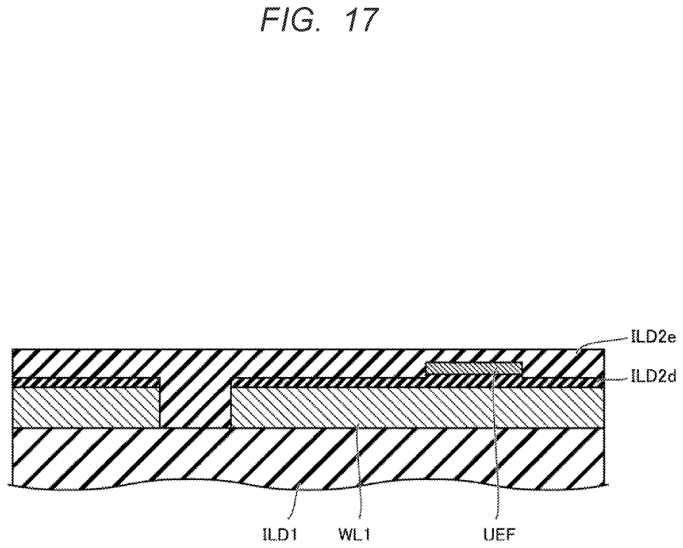

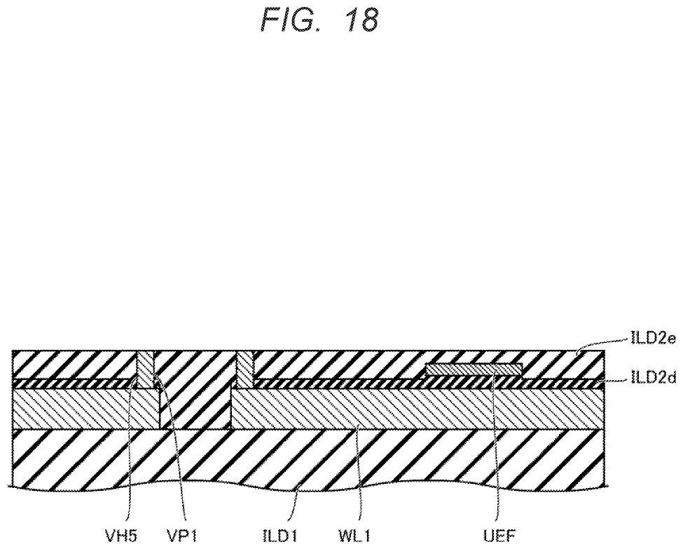

FIG. 17 is a cross-sectional view for explaining the second layer forming step S14. As shown in FIG. 17, in the second layer forming step S14, the second layer ILD2e is formed by forming the constituent material of the second layer ILD2e so as to cover the wiring layer WL1 and the upper electrode film UEF and planarizing the constituent material of the second layer ILD2e formed with CMP or the like. FIG. 18 is a cross-sectional view for explaining the first via plug forming step S15. As shown in FIG. 18, in the first via plug forming step S15, the via hole VH5 is formed in the first layer ILD2d and the second layer ILD2e, and the via plug VP1 is embedded in the via hole VH5.

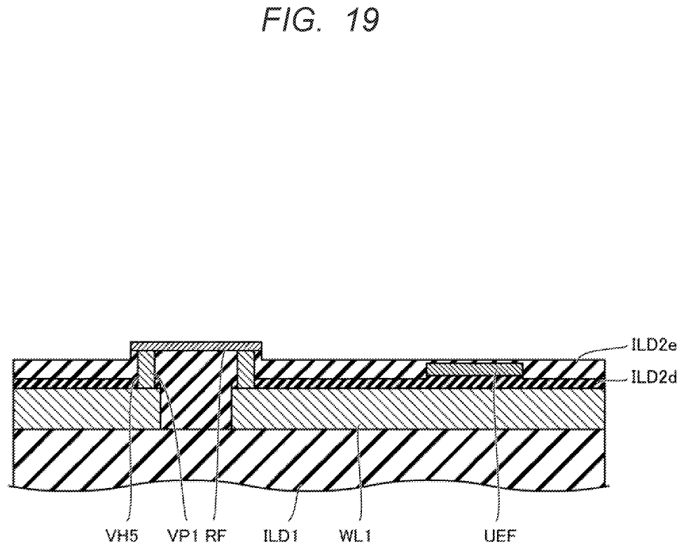

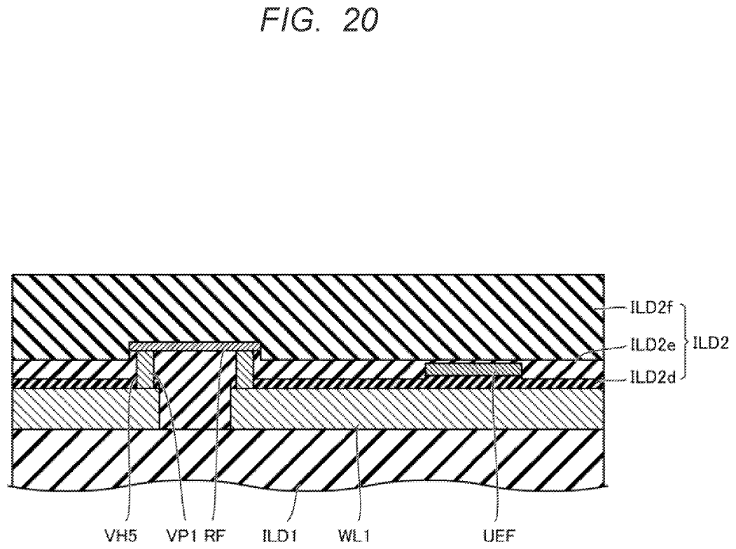

FIG. 19 is a cross-sectional view for explaining the resistance film forming step S16. As shown in FIG. 19, in the resistance film forming step S16, a resistance film RF is formed on the second layer ILD2e. The resistance film RF is formed by forming a constituent material of the resistance film RF and patterning a constituent material of a dry etching formed by using a resist pattern as a mask. FIG. 20 is a cross-sectional view for explaining the third layer forming step S17. In the third layer forming step S17, as shown in FIG. 20, the third layer ILD2f is formed so as to cover the resistance film RF.

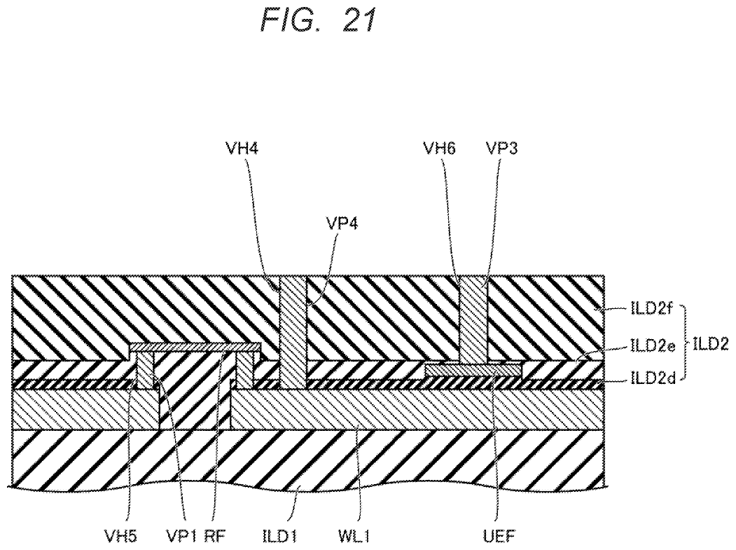

FIG. 21 is a cross-sectional view for explaining a second via plug forming step S18. As shown in FIG. 21, in the second via plug forming step S18, first, the via hole VH5 is formed in the second layer ILD2e and the third layer ILD2f, and the via hole VH4 is formed in the interlayer insulating film ILD2. Second, the via plug VP3 and the via plug VP4 are embedded to the via hole VH5 and the via hole VH4, respectively. Thereafter, the second wiring layer forming step S12 is performed to form the semiconductor device DEV1 of structure shown in FIG. 14.

In the semiconductor device DEV1, in the first via plug forming step S15, when the constituent material of the via plug VP1 protruding from the via hole VH1 is removed by CMP or the like, a part of the second layer ILD2e may be removed or the upper electrode film UEF may be exposed from the second layer ILD2e.

In the semiconductor device DEV1, in the resistance film forming step S16, the constituent material of the resistance film RF is patterned by dry etching. The resistance film RF constituent materials such as silicon chrome, nichrome, and tantalum nitride are difficult to perform dry etching (in the case of dry etching, it is difficult to ensure a selectivity with respect to silicon oxide, which is a constituent material of the interlayer insulating film ILD2), so that the second layer ILD2e can be etched greatly when patterning the constituent material of the resistance film RF. As a result, exposed of the upper electrode film UEF, loss of the upper electrode film UEF, damage to UEF of the upper electrode film UEF, and the like may occur.

In order to solve this problem, the thickness of the second layer ILD2e needs to be increased. In order to increase the thickness of the second layer ILD2e without increasing the thickness of the interlayer insulating film ILD2, the thickness of the third layer ILD2f needs to be reduced. However, when the thickness of the third layer ILD2f is reduced, in the second via plug forming step S18, when the constituent material of the via plug VP3 protruding from the via hole VH5 and the constituent material of the via plug VP4 protruding from the via hole VH4 are removed by CMP or the like, the resistance film RF may be exposed or the resistance film RF may be lost from the third layer ILD2f. Thus, in the semiconductor device DEV1, it is necessary to increase the thickness of the interlayer insulating film ILD2 to ensure the thickness of the second layer ILD2e and the thickness of the third layer ILD2f.

Note that when the thickness of the interlayer insulating film ILD2 is increased, the capacitance parameter is changed, and the circuit IP needs to be redesigned. Further, as the thickness of the interlayer insulating film ILD2 is increased, width of the via plug VP4 is increased, and accordingly, a wiring pitch of the wiring layer WL1 needs to be increased.

On the other hand, in the semiconductor device DEV, since the upper electrode film UEF is made of a material that is easy to dry etching, even if the thickness of the second layer ILD2b is small, an exposure of the lower electrode film LEF (the first film FF) and a damage to the lower electrode film LEF are unlikely to occur during dry etching in the second film patterning step S8. Therefore, in the semiconductor device DEV, the thickness of the third layer ILD2c can be secured without increasing the thickness of the interlayer insulating film ILD2, and the upper electrode film UEF can be suppressed from being exposed or disappeared when the second via plug forming step S11 is performed. As described above, according to the semiconductor device DEV, it is possible to arrange the MIM capacitor in the interlayer insulating film ILD2 without increasing the thickness of the interlayer insulating film ILD2.

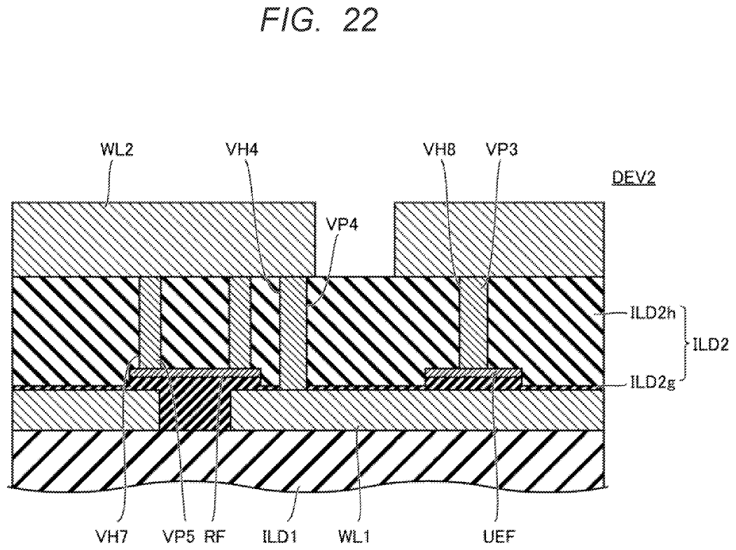

FIG. 22 is a cross-sectional view of a semiconductor device DEV2. As shown in FIG. 22, the semiconductor device DEV2 includes an interlayer insulating film ILD1 and an interlayer insulating film ILD2, a wiring layer WL1 and a wiring layer WL2, a via plug VP3, a via plug VP4, and a via plug VP5, a resistance film RF, and an upper electrode film UEF.

In the semiconductor device DEV2, the interlayer insulating film ILD2 has a first layer ILD2g and a second layer ILD2h. In the semiconductor device DEV2, the resistance film RF and the upper electrode film UEF are made of the same material and are disposed on the first layer ILD2g. In the semiconductor device DEV2, the first layer ILD2g between the wiring layer WL1, the upper electrode film UEF, and the wiring layer WL1 and the upper electrode film UEF constitutes a MIM capacitor. That is, in the semiconductor device DEV2, the wiring layer WL1 function as a lower electrode. The second layer ILD2h is disposed on the first layer ILD2g so as to cover the resistance film RF and the upper electrode film UEF.

In the semiconductor device DEV2, a via hole VH7 and a via hole VH8 are formed in the second layer ILD2h. The via plug VP5 is embedded to the via hole VH7, so that the resistance film RF and the wiring layer WL2 are electrically connected to each other. When the via plug VP3 is embedded to the via hole VH8, the upper electrode film UEF and the wiring layer WL2 are electrically connected to each other.

As described above, the constituent material of the resistance film RF is a material that cannot increase selectivity with respect to the constituent material of the interlayer insulating film ILD2 during dry etching. Therefore, in the semiconductor device DEV2, when the via hole VH7 and the via hole VH8 are formed by dry etching, the resistance film RF and the upper electrode film UEF formed of the same material as the resistance film RF are also etched, the via hole VH8 may be reached to the upper electrode film UEF while the via hole VH7 reaches the resistance film RF. As a result, the contact between the via plug VP7 and the resistance film RF and the contact between the via plug VP3 and the upper electrode film UEF become insufficient, and these contact-resistances will be increased.

In addition, in the semiconductor device DEV2, the thickness of the first layer ILD2g constituting the dielectric film of the MIM capacitor cannot be increased from the viewpoint of ensuring the characteristics of the MIM capacitor. The wiring layer WL1 may be exposed by dry etching when forming the resistance film RF and the upper electrode film UEF, and the wiring layer WL1 may be damaged.

On the other hand, in the semiconductor device DEV, dry etching for forming the via hole VH3 is easily stopped at the upper electrode film UEF. Since the upper electrode film UEF is formed of a material which is easy to ensure a selectivity with the constituent material (silicon oxide) of the interlayer insulating film ILD2 during dry etching. Further, in the semiconductor device DEV, since the upper electrode film UEF is not made of the same material as the resistance film RF, the contact-resistance with the via plug VP3 is unlikely to increase. Furthermore, in the semiconductor device DEV, since the first layer ILD2a does not constitute the dielectric film of the MIM capacitor, it is possible to secure the thickness of the first layer ILD2a. And even if the first layer ILD2a is etched greatly by dry etching when forming the resistance film RF and the lower electrode film LEF, the wiring layer WL1 is hardly exposed.

Although the invention made by the present inventors has been described in detail based on the embodiments, it is needless to say that the present invention is not limited to the above-described embodiments and can be variously modified without departing from the gist thereof.

What is claimed is:

1. A semiconductor device comprising:
an interlayer insulating film having a first layer, a second layer and a third layer;
a resistance film and a lower electrode film formed on the first layer respectively;
the second layer formed on the resistance film and the lower electrode film;
an upper electrode film formed on the second layer; and
the third layer formed on the upper electrode film, wherein
the resistance film and the lower electrode film are made of the same material, and
the lower electrode film and the upper electrode film are opposed to each other via the second layer.

2. The semiconductor device according to claim 1, wherein
the second layer is interposed between the third layer and the lower electrode film.

3. The semiconductor device according to claim 1, wherein
the resistance film and the lower electrode film are located separate apart from each other.

4. The semiconductor device according to claim 1, further comprising:
a first wiring layer formed under the first layer;
a first via plug formed in the first layer;
a second wiring layer formed on the third layer; and
a second via plug formed in the third layer, wherein
the lower electrode film and the first wiring layer are electrically coupled via the first via plug, and
the upper electrode film and the second wiring layer are electrically coupled via the second via plug.

5. The semiconductor device according to claim 1, wherein
the resistance film is made of metal material.

6. The semiconductor device according to claim 5, wherein
the metal material includes at least one selected from the group consisting of silicon chrome, carbon introduced silicon chrome, nichrome and tantalum nitride.

7. The semiconductor device according to claim 1, wherein
the upper electrode film is made of titanium nitride.

8. The semiconductor device according to claim 1, wherein
the interlayer insulating film is made of silicon oxide.

9. The semiconductor device according to claim 4, wherein
the first wiring layer and the second wiring layer are made of aluminum or aluminum alloy.

10. The semiconductor device according to claim 1, wherein
a thickness of the resistance film is the same as a thickness of the lower electrode film.

11. The semiconductor device according to claim 1, wherein
a thickness of the second layer is smaller than a thickness of the first layer and a thickness of the third layer.

12. The semiconductor device according to claim 1, wherein
a total thickness of the first layer, the second layer and third layer are 650 nm or more.

13. The semiconductor device according to claim 1, wherein
the lower electrode film, the upper electrode film, and the second layer configure a MIM capacitor.

14. A manufacturing method of a semiconductor device, comprising the steps of:
(a) forming a first layer;
(b) forming a first film on the first layer;
(c) patterning the first film to form a resistance film and a lower electrode film;
(d) forming a second layer so as to cover the resistance film and the lower electrode film;
(e) forming a second film on the second layer;
(f) patterning the first film to form an upper electrode film; and
(g) forming a third layer so as to cover the upper electrode film, wherein
the lower electrode film and the upper electrode film are opposed to each other via the second layer.

15. The manufacturing method of the semiconductor device according to claim 14, wherein
in the step of (c), the patterning the first film is performed by dry etching process.
